(19) United States
(12) Patent Application Publication
(10) Pub. No.: US 2015/0037979 A1
(43) Pub. Date: Feb. 5, 2015

(54) CONFORMAL SIDEWALL PASSIVATION

(71) Applicant: Lam Research Corporation, Fremont, CA (US)

(72) Inventor: Eric A. HUDSON, Berkeley, CA (US)

(73) Assignee: Lam Research Corporation, Fremont, CA (US)

(21) Appl. No.: 13/958,393

(22) Filed: Aug. 2, 2013

(51) Int. Cl. H01L 21/308; H01L 21/3065

(52) U.S. Cl. CPC H01L 21/308; H01L 21/3065
USPC 438/694; 438/706; 438/710

(57) ABSTRACT

A method for etching features into an etch layer in a stack disposed below a patterned mask with mask features is provided. Coating providing molecules are provided. The coating providing molecules are pyrolyzed, which only produces a first set of byproducts and a second set of byproducts, wherein the first set of byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶. The stack is exposed to the first set of byproducts, causing the first set of byproducts to deposit a coating. The etch layer is etched.

### BACKGROUND OF THE INVENTION

### Field of the Invention

The invention relates to a method of forming semiconductor devices on a semiconductor wafer.

In forming semiconductor devices, some devices may be etched to provide wide and narrow features. Some of the features may be high aspect ratio features.

### SUMMARY OF THE INVENTION

To achieve the foregoing and in accordance with the purpose of the present invention, a method for etching features into an etch layer in a stack disposed below a patterned mask with mask features is provided. Coating providing molecules are provided. The coating providing molecules are pyrolyzed, which only produces a first set of byproducts and a second set of byproducts, wherein the first set of byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶. The stack is exposed to the first set of byproducts, causing the first set of byproducts to deposit a coating. The etch layer is etched.

In another manifestation of the invention, a method for etching features into an etch layer disposed below a patterned mask, comprising performing at least three cycles is provided. Each cycle comprises providing, by creating a plasma, an ion bombardment of the etch layer to create activated sites in parts of the etch layer exposed by the patterned mask, extinguishing the plasma, exposing the etch layer to a first set of fluorocarbon byproducts, which causes the first set of fluorocarbon byproducts to selectively bind to the activated sites, wherein the selective binding is self limiting, and providing an ion bombardment of the etch layer to initiate an etch reaction between the first set of fluorocarbon byproducts and the etch layer, wherein the ion bombardment of the etch layer to initiate an etch reaction causes the formation of volatile etch products formed from the etch layer and the first set of fluorocarbon byproducts. The first set of fluorocarbon byproducts are formed by the method comprising providing coating providing molecules and pyrolyzing the coating providing molecules, which only produce the first set of fluorocarbon byproducts and a second set of byproducts, wherein the first set of fluorocarbon byproducts have a sticking coefficient between 10⁻⁶ to 5×10⁻³ at non-activated sites and wherein the second set of byproducts includes all remaining byproducts from the pyrolysis, wherein all remaining byproducts from the pyrolysis have sticking coefficients less than 10⁻⁶ at non-activated sites.

In another manifestation of the invention, a method for plasma processing a wafer is provided. An interior of a process chamber is coated, comprising providing coating providing molecules, pyrolyzing the coating providing molecules, which only produce a first set of byproducts and a second set of byproducts, wherein the first set of byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶, and exposing the interior of the process chamber to the first set of byproducts, causing the first set of byproducts to deposit a coating on the interior of the process chamber. The stack is placed in the process chamber. The wafer is processed in the process chamber.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIG. 2 is a more detailed flow chart of the step of depositing a coating.

FIGS. 3A-F are schematic cross-sectional views of a stack processed according to an embodiment of the invention.

FIG. 4 is a schematic view of an etching chamber that may be used in an embodiment of the invention.

FIG. 5 is a schematic view of a computer system that may be used in practicing the invention.

FIG. 6 is a schematic cross-sectional view of a stack processed according to the prior art.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

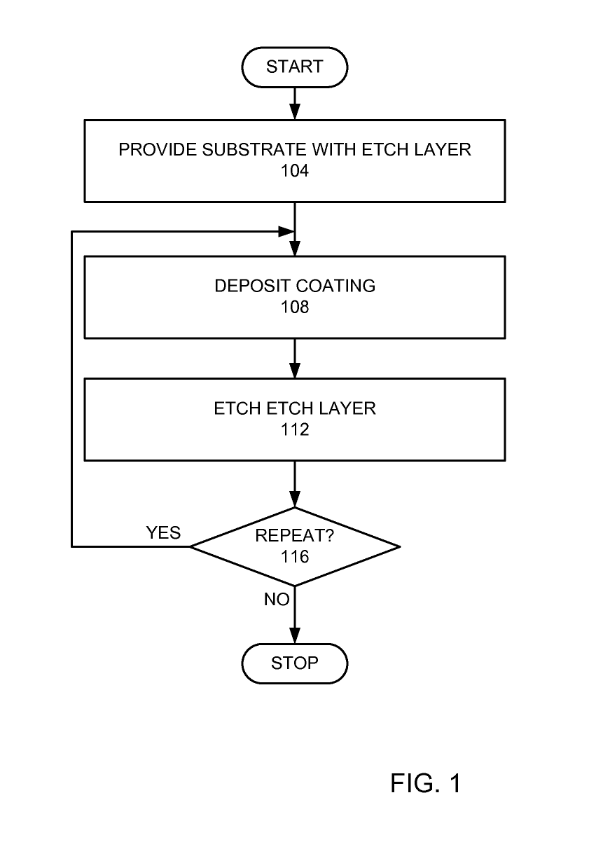

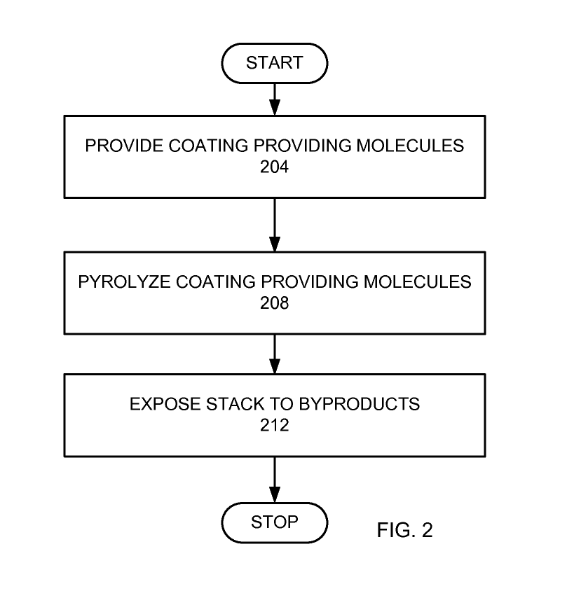

FIG. 1 is a high level flow chart of an embodiment of the invention. In this embodiment, a substrate with an etch layer is provided (step 104). Preferably, the etch layer is disposed below a patterned mask. A coating is deposited (step 108). FIG. 2 is a more detailed flow chart of the step of depositing the coating. Coating providing molecules are provided (step 204). The coating providing molecules are pyrolyzed to form byproducts (step 208). The byproducts consist of a first set of byproducts having a sticking coefficient between 10⁻⁶ to 5×10⁻³ and a second set of byproducts including all remaining byproducts from the pyrolysis, wherein all remaining byproducts from the pyrolysis have sticking coefficients less than 10⁻⁶. The stack is exposed to the byproducts (step 212). Byproducts from the first set of byproducts form the coating. The etch layer is etched (step 112). In some embodiments of the invention, the process may be repeated (step 116).

### EXAMPLE

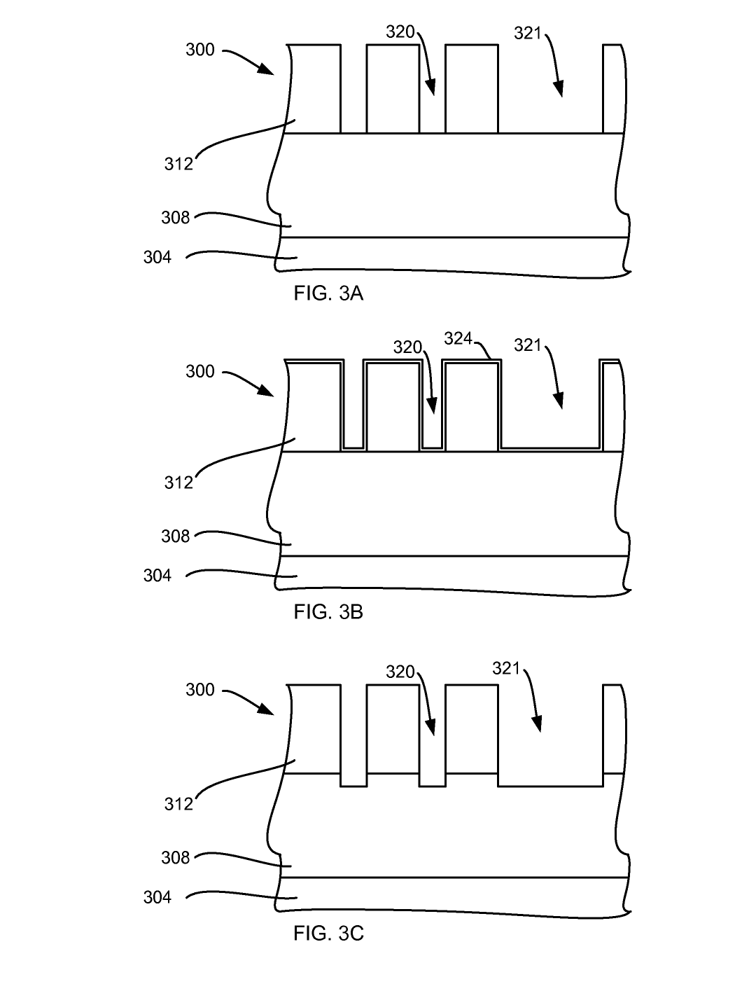

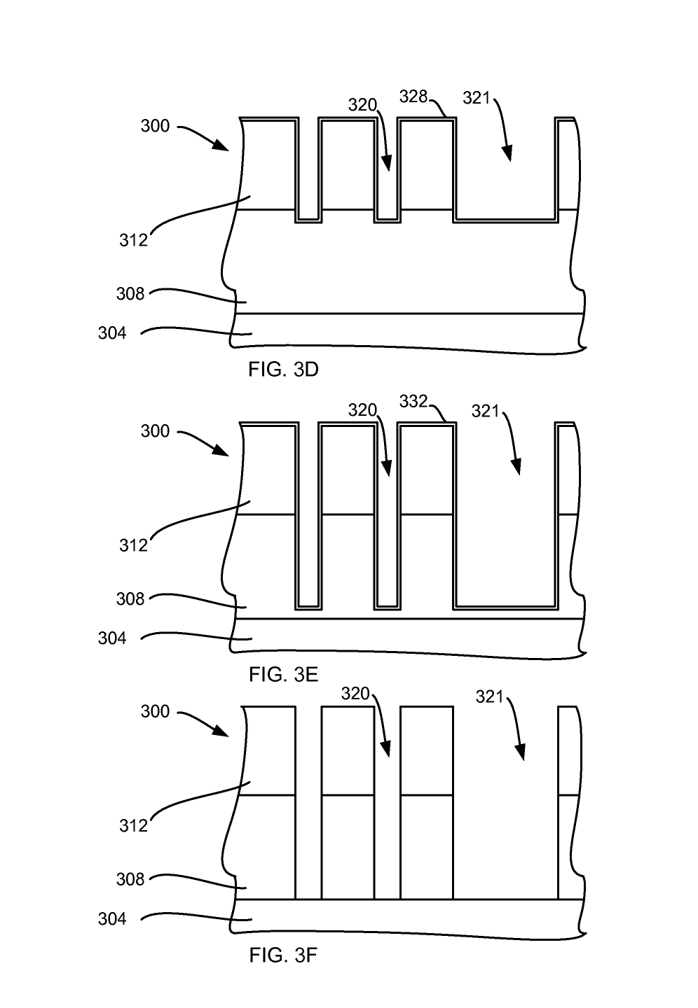

In a preferred embodiment of the invention, a substrate with an etch layer of silicon oxide is disposed under a patterned mask (step 104). FIG. 3A is a schematic cross-sectional view of a stack 300 with a substrate 304 with an etch layer 308 disposed below a patterned mask 312. In this example, one or more layers may be disposed between the substrate 304 and the etch layer 308, or the etch layer 308 and the patterned mask 312. In this example, the patterned mask 312 is poly-silicon, and the etch layer 308 is a silicon oxide based dielectric. Other embodiments may use other key mask materials, such as spin-on organic mask layer and α-C, amorphous carbon layer (ACL). In this example, mask pattern features 320, 321 have been formed in the patterned mask 312. In some embodiments, the mask pattern features 320, 321 are formed before the substrate 304 is placed in the chamber. In other embodiments, the mask pattern features 320, 321 are formed while the substrate 304 is in the chamber. As shown, some mask pattern features 321 may be wider than other mask pattern features 320. The width is not the only factor that affects shading—the shape of the hole also matters. In this example, one mask pattern feature 321 is several times wider than another mask pattern feature 320. The stack 300 is placed in a processing chamber.

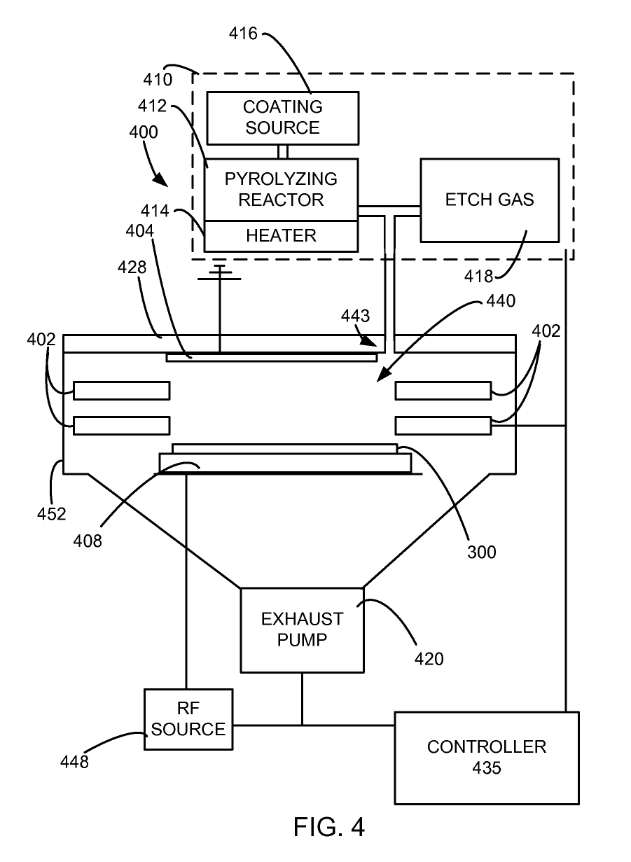

FIG. 4 is a schematic view of a processing chamber 400 that may be used for one or more of the following steps. The processing chamber 400 comprises confinement rings 402, an upper electrode 404, a lower electrode 408, a gas source 410, and an exhaust pump 420. Within a processing chamber 400, the stack 300 is positioned upon the lower electrode 408. The lower electrode 408 incorporates a suitable substrate chucking mechanism (e.g., electrostatic, mechanical clamping, or the like) for holding the stack 300. The reactor top 428 incorporates the upper electrode 404 disposed immediately opposite the lower electrode 408. The upper electrode 404, lower electrode 408, and confinement rings 402 define the confined plasma volume 440. Gas is supplied to the confined plasma volume 440 through a gas inlet 443 by the gas source 410 and is exhausted from the confined plasma volume 440 through the confinement rings 402 and an exhaust port by the exhaust pump 420. Besides helping to exhaust the gas, the exhaust pump 420 helps to regulate pressure. In this embodiment, the gas source 410 comprises coating providing gas source 416, a pyrolyzing reactor 412 with a heater 414, and an etch gas source 418. The gas source 410 may further comprise other gas sources. An RF source 448 is electrically connected to the lower electrode 408. Chamber walls 452 surround the confinement rings 402, the upper electrode 404, and the lower electrode 408. Different combinations of connecting RF power to the electrode are possible. In a preferred embodiment, the 27 MHz, 60 MHz and 2 MHz power sources make up the RF power source 448 connected to the lower electrode 408, and the upper electrode 404 is grounded. A controller 435 is controllably connected to the RF source 448, exhaust pump 420, and the gas source 410. Preferably, the process chamber 400 is a CCP (capacitive coupled plasma) reactor, as shown. In other embodiments, an ICP (inductive coupled plasma) reactor or other sources like surface wave, microwave, or electron cyclotron resonance ECR may be used.

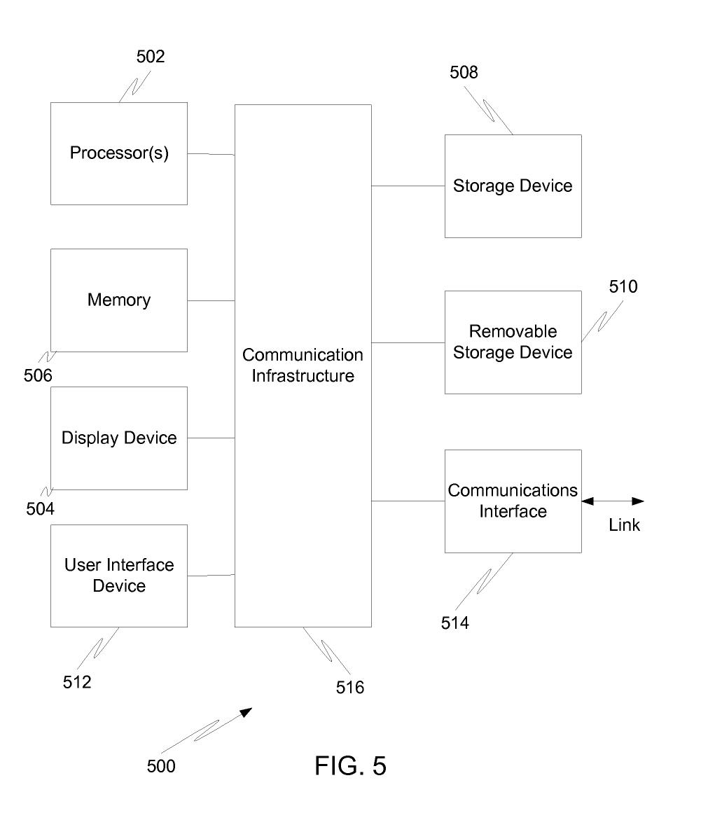

FIG. 5 is a high level block diagram showing a computer system 500, which is suitable for implementing a controller 435 used in embodiments of the present invention. The computer system may have many physical forms ranging from an integrated circuit, a printed circuit board, and a small handheld device up to a huge super computer. The computer system 500 includes one or more processors 502, and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and a communication interface 514 (e.g., wireless network interface). The communication interface 514 allows software and data to be transferred between the computer system 500 and external devices via a link. The system may also include a communications infrastructure 516 (e.g., a communications bus, cross-over bar, or network) to which the aforementioned devices/modules are connected.

Information transferred via communications interface 514 may be in the form of signals such as electronic, electromagnetic, optical, or other signals capable of being received by communications interface 514, via a communication link that carries signals and may be implemented using wire or cable, fiber optics, a phone line, a cellular phone link, a radio frequency link, and/or other communication channels. With such a communications interface, it is contemplated that the one or more processors 502 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

After the substrate 304 has been placed into the processing chamber 400, a coating is deposited (step 108). In this embodiment, a coating providing molecule gas is flowed (step 204). In this example, the coating providing molecule gas is 2000 sccm 2,2,3-Trifluoro-3-(trifluoromethyl)oxirane, which is flowed into the pyrolyzing reactor 412 (step 204). The heater 414 provides a sufficient temperature, which in this embodiment is above 150° C., to pyrolyze an appreciable fraction of the coating providing molecule gas into by products (step 208). In this example, the wall materials of the pyrolyzing reactor 412 are stainless steel, to catalyze efficient pyrolysis which might otherwise require much higher temperatures. Other potential catalyzing wall materials include tantalum, tungsten, and nickel-chromium alloy. In an alternative embodiment, large surface areas of the catalytic metallic materials could be introduced in the pyrolyzing reactor 412 to promote higher pyrolysis efficiency, for example as thin filaments or sheets.

In this embodiment, a first set of byproducts is CF₂, which when formed by pyrolysis from 2,2,3-Trifluoro-3-(trifluoromethyl)oxirane is estimated to have a sticking coefficient of about 10⁻⁵ to 10⁻⁴ for substrates in 0°-60° C. temperature range Such a sticking coefficient is lower than the sticking coefficient of CF₂ in the presence of plasma, which is reported to have a sticking coefficient of greater than 10⁻². The remaining byproducts have a sticking coefficient of less than 10⁻⁶.

The stack 300 is exposed to the byproducts (step 212). In this embodiment, the first set of byproducts form a conformal coating. Due to the very low sticking coefficient, such a conformal coating deposits a uniform thickness on the sidewalls with little dependence upon aspect ratio for high aspect ratio features. FIG. 3B is a schematic cross-sectional view of the stack 300 after the conformal coating 324 has been deposited. The conformal coating 324 may be thinner than shown, however the drawings are not to scale in order to better illustrate various aspects of the embodiments.

The etch layer 308 is etched (step 112). In this embodiment, to etch a silicon oxide based etch layer, an etch gas of CF₄ at a pressure of 40 mT is introduced to a capacitively coupled plasma with RF power of 400 W at a frequency of 27 MHz. FIG. 3C is a schematic cross-sectional view of the stack 300 after the etch layer 308 has been partially etched. In this embodiment a significant amount or all of the conformal coating has been etched away, and therefore is not shown. In other embodiments, less of the conformal coating is etched away or the conformal coating may be selectively etched, such as horizontal surfaces of the conformal coating may be selectively etched with respect to vertical surfaces of the conformal coating.

In this embodiment, the process is repeated (step 116). A conformal coating is deposited using the previous deposition recipe (step 108). FIG. 3D is a schematic cross-sectional view of the stack 300 after a conformal coating 328 has been deposited. FIG. 3E is a schematic cross-sectional view of the stack 300 after a conformal coating 332 has been deposited after several cycles have been repeated. Although the features 320, 321 have a higher aspect ratio, the conformal coating 332 has substantially vertical and uniformly deposited sidewall coatings. In addition, the uniformity continues for high aspect ratio features. FIG. 3F is a schematic cross-sectional view of the stack 300 after the features 320, 321 are completely etched through the etch layer 308.

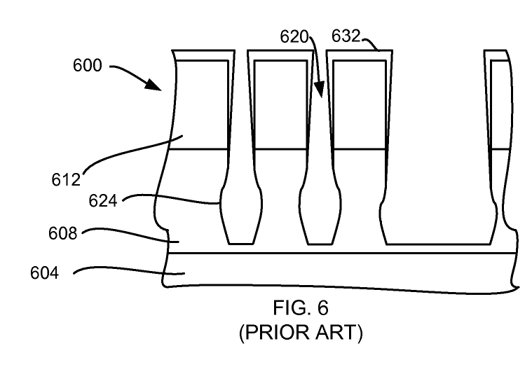

In the prior art, deposition components with sticking coefficients higher than 5×10⁻³ are used. For example, a prior art process may use a plasma to create fluorocarbon species with sticking coefficients of greater than 10⁻¹. The fluorocarbon species are used to form a coating. FIG. 6 is a schematic cross-sectional view of a stack 600 with a substrate 604 with an etch layer 608 disposed below a patterned mask 612. Features 620 have been partially etched into the etch layer 608. A coating 632 is formed using a plasma generated fluorocarbon species with a sticking coefficient of greater than 10⁻¹. Because of the higher sticking coefficient, more fluorocarbon species deposits nearer to the tops of the features 620 than closer to the bottom. In this example, very little to none of the fluorocarbon species deposits on sidewalls for the bottom half of the features 620. Since there is little to no deposition on the sidewalls of the bottom half of the features 620, the sidewalls on the bottom half of the features 620 are etched causing the features 620 to have a bowing profile 624. In addition, for narrower features 620 the coating does not deposit as far down compared to wider features 620. Therefore, the prior art increases bowing in high aspect ratio features and produces features with profiles, which are dependent upon feature aspect ratio. It is estimated that CF₂ created in a prior art plasma process would have a sticking coefficient greater than 10⁻². This relatively high sticking coefficient may result from plasma activation of CF₂ molecular excited states and/or plasma-induced chemical transformations of CF₂, which create more reactive fluorocarbon radicals such as CF, CF3, C2F5, etc. It was believed that a higher sticking coating was more desirable for improving the speed of depositing the coating, however there are drawbacks due to the aspect ratio dependence of sidewall deposition rate.

By using coating species with sticking coefficients between 10⁻⁶ and 5×10⁻³, according to embodiments of the invention, the sticking coefficient is high enough to form a coating and low enough to allow the species to collide with the sidewalls many times before sticking. Because the species are able to collide with the sidewalls many times before sticking, instead of mainly depositing near the top, a high fraction of the species is able to reach the bottom of the features providing a more uniform sidewall coating vs. depth. The more uniform sidewall coating reduces bowing by protecting the feature sidewall from lateral etching. Preferably, the coating process is plasma free to provide a lower sticking coefficient and an improved coating. In other embodiments, a plasma may be added to the flow of the coating byproducts. The plasma may produce some species with a higher effective sticking coefficient, but some benefits may still be realized from the remaining fraction of coating species with sticking coefficients between 10⁻⁶ and 5×10⁻³.

In another embodiment of the invention, the coating is thick enough to appreciably shrink the CD of the features. Since the coating is uniform and even from top to bottom and the thickness of the coating may be made independent of the width of the features, the coating provides a more uniform and vertical shrink compared to conventional methods. Additionally the amount of CD shrink is nearly independent of the original feature CD and shape. This aspect ratio-independent CD shrink capability may have useful applications.

In various embodiments of the invention, various processes may be used to provide pyrolysis. Preferably, the pyrolysis is provided at a temperature between 100° C. to 2000° C. Other metal catalysts may be used to facilitate pyrolysis, such as using a hot wire deposition process. In other embodiments, the pyrolysis is performed without a catalyst. The pyrolysis may be performed within the etch reactor or outside of the etch reactor, where the byproducts are then flowed into the etch reactor. In other embodiments, the deposition may be performed in a separate chamber from etching.

In other embodiments the coating providing molecules may be 2,2,3-Trifluoro-3-(trifluoromethyl)oxirane, cyclo-perfluoropropane, dimethyldiazene, or ethane. Preferably, the coating providing molecules have a favorable first order reaction to produce CF₂ or CH₃ and stable byproduct molecules. Such coatings provide many advantages and uses for etching.

The coating preferably is highly conformable, provides good step coverage with low dependence on aspect ratio and geometry. Such a coating provides sidewall passivation for etching to reduce bowing. Such coatings also improve profile control. If the coating is used to provide CD shrink, the coating has minimal feature loading based on CD and geometry. Additionally the coating provides a vertical profile after CD shrink.

In one embodiment, in addition to coating the wafer, the first set of byproducts may coat the interior of the processing chamber 400. This coating may both protect the processing chamber surface from subsequent plasma-induced modifications and may also provide a more uniform and conformal coating process. The coating of the interior of the processing chamber 400 may be removed during the etch or after the stack 300 is removed from the processing chamber. In another embodiment, the first set of byproducts are created and exposed to the interior of the processing chamber 400 to coat the interior of the processing chamber before the stack 300 is placed in the processing chamber. In addition, the coating on the interior of the processing chamber 400 may be removed after the stack 300 is removed from the processing chamber 400. The coating the chamber and removing the coating may be repeated for each stack 300.

Such a coating may also be selectively deposited on activated sited, which are activated by ion deposition. Such a process may use ion bombardment of the bottoms of features to create activated sites on the bottoms of the features. The coating is selectively deposited on the activated sites, which effectively have very high local sticking coefficients. If the coating is composed of etchant-containing material, a subsequent bombardment can transform the coating to cause the coating to etch the etch layer at the activated sites. The use of ion bombardment to create activated sites, then the exposure of fluorocarbon to bind on the activated sites, and then the use of ion bombardment to etch the activated sites is described in U.S. patent application Ser. No. 13/937,930, entitled “FLUOROCARBON BASED ASPECT-RATIO INDEPENDENT ETCHING,” BY Bhowmick et al., filed on Jul. 9, 2013, which is incorporated by reference for all purposes. The benefit of using the inventive coating is that the deposition rate at ion activated sites will be substantially independent of aspect ratio, therefore the resulting etch rate will also be independent of AR.

U.S. Pat. No. 7,767,584, entitled, “IN-SITU PRE-COATING OF PLASMA ETCH CHAMBER FOR IMPROVED PRODUCTIVITY AND CHAMBER CONDITIONING CONTROL,” by Singh et al., issued Aug. 3, 2010, which is incorporated by reference for all purposes, discloses an etch process, which coats the inner surface of a chamber with a silicon containing coating, etches an etch wafer on a substrate and the cleans the coating. The coating provided by embodiments of the invention may be used to pre-coat the inner surface of a chamber. Such a coating would be very conformal and uniform and does not require a plasma.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A method for etching features into an etch layer in a stack disposed below a patterned mask with mask features, comprising:
providing coating providing molecules;
pyrolyzing the coating providing molecules, which only produce a first set of byproducts and a second set of byproducts, wherein the first set of byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶;
exposing the stack to the first set of byproducts, causing the first set of byproducts to deposit a coating; and
etching the etch layer.

2. The method, as recited in claim 1, wherein the exposing the substrate to the first set of byproducts and etching the etch layer are performed in separate steps that are cyclically repeated for a plurality of cycles.

3. The method, as recited in claim 2, wherein the pyrolyzing the coating providing molecules and the exposing the stack to the first set of byproducts are plasma free processes.

4. The method, as recited in claim 3, wherein the first set of byproducts conformally coats features in the etch layer.

5. The method, as recited in claim 4, wherein the first set of byproducts comprises at least one of CF₂ or CH₃.

6. The method, as recited in claim 4, wherein the first set of byproducts comprises CF₂.

7. The method, as recited in claim 6, wherein the etch layer is a silicon-containing dielectric or conductive layer.

8. The method, as recited in claim 7, wherein the coating providing molecules comprise 2,2,3-Trifluoro-3-(trifluoromethyl)oxirane or cyclo-perfluoropropane.

9. The method, as recited in claim 4, wherein the first set of byproducts comprises CH₃.

10. The method, as recited in claim 9, wherein the coating providing molecules comprise at least one of dimethyldiazene or ethane.

11. The method, as recited in claim 1, wherein the exposing the substrate to the first set of byproducts and the etching the etch layer are performed simultaneously.

12. The method, as recited in claim 1, wherein the etch layer is a silicon-containing dielectric or conductive layer.

13. The method, as recited in claim 12, wherein the coating providing molecules comprise 2,2,3-Trifluoro-3-(trifluoromethyl)oxirane or cyclo-perfluoropropane.

14. The method, as recited in claim 1, wherein the first set of byproducts comprises CH₃.

15. The method, as recited in claim 14, wherein the coating providing molecules comprise at least one of dimethyldiazene or ethane.

16. The method, as recited in claim 1, wherein features in the etch layer have smaller CDs than CDs in corresponding mask features in the patterned mask.

17. A method for etching features into an etch layer disposed below a patterned mask, comprising performing at least three cycles, wherein each cycle comprises:
Providing, by creating a plasma, an ion bombardment of the etch layer to create activated sites in parts of the etch layer exposed by the patterned mask;
extinguishing the plasma;
exposing the etch layer to a first set of fluorocarbon byproducts, which causes the first set of fluorocarbon byproducts to selectively bind to the activated sites, wherein the selective binding is self limiting, wherein the first set of fluorocarbon byproducts are formed by the method, comprising
providing coating providing molecules; and
pyrolyzing the coating providing molecules, which only produce the first set of fluorocarbon byproducts and a second set of byproducts, wherein the first set of fluorocarbon byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶; and
providing an ion bombardment of the etch layer to initiate an etch reaction between the first set of fluorocarbon byproducts and the etch layer, wherein the ion bombardment of the etch layer to initiate an etch reaction causes the formation of volatile etch products formed from the etch layer and the first set of fluorocarbon byproducts.

18. The method, as recited in claim 17, further comprising removing unbound byproducts of the first set of fluorocarbon byproducts that are not bound to the activated sites, before providing the ion bombardment of the etch layer to initiate the etch reaction.

19. A method for plasma processing a wafer, comprising:
a) coating an interior of a process chamber, comprising:
providing coating providing molecules;
pyrolyzing the coating providing molecules, which only produce a first set of byproducts and a second set of byproducts, wherein the first set of byproducts have a sticking coefficient between 10⁻⁶ to 5×10⁻³ and wherein the second set of byproducts includes all remaining byproducts from the pyrolysis wherein all remaining byproducts from the pyrolysis have sticking coefficients less than 10⁻⁶; and
exposing the interior of the process chamber to the first set of byproducts, causing the first set of byproducts to deposit a coating on the interior of the process chamber;
b) placing the stack in the process chamber; and
c) processing the wafer in the process chamber.

20. The method, as recited in claim 19, further comprising:
d) removing the stack from the process chamber;
e) cleaning the interior of the process chamber; and
f) repeating steps a through e.
